(19) United States
(12) Patent Application Publication
(10) Pub. No.: US 2025/0287560 A1
(43) Pub. Date: Sep. 11, 2025

(54) Parameterizing an Electronics Production Line

(71) Applicant: Siemens Aktiengesellschaft, München (DE)

(72) Inventors: Bernd Müller, Falkenberg (DE); Ulrich Wittreich, Velten (DE); Michael Erdmann, Borkheide (DE); Kay Jarchoff, Schönfließ (DE); Carsten Borwieck, Berlin (DE); Michael Hanisch, Hohen Neuendorf (DE)

(73) Assignee: Siemens Aktiengesellschaft, München (DE)

(21) Appl. No.: 18/851,945

(22) PCT Filed: Jan. 19, 2023
(86) PCT No.: PCT/EP2023/051224

§ 371 Date: Sep. 27, 2024

(30) Foreign Application Priority Data
Mar. 30, 2022 (EP) 22165500.4

(51) Int. Cl. H05K 13/08; H05K 13/00; H05K 13/04

(52) U.S. Cl. CPC H05K 13/083; H05K 13/0015; H05K 13/0465; H05K 13/0495; H05K 13/0882

(57) ABSTRACT

Various embodiments include a method for parameterizing an electronics production line using device parameters of a reference production line. The electronics production lines each include: a device to apply joining material to component carriers, a placement device to place electronic components onto the component carriers, a joining device to connect the electronic components to the component carriers, and a transport system to transport the component carriers through the devices. An example method includes: parameterizing the devices of the production line using parameters of the reference line; ascertaining actual parameter values in a limited region around the transport system; and ascertaining deviations between the actual process parameter values and reference process parameter values. The reference process parameter values have been acquired in a limited region around the transport system of the reference production line.

### CROSS-REFERENCE TO RELATED APPLICATIONS

This application is a U.S. National Stage Application of International Application No. PCT/EP2023/051224 filed Jan. 19, 2023, which designates the United States of America, and claims priority to EP application Ser. No. 22/165,500.4 filed Mar. 30, 2022, the contents of which are hereby incorporated by reference in their entirety.

### TECHNICAL FIELD

The present disclosure relates to production lines. Various embodiments of the teachings herein include systems and/or methods for parameterizing an electronics production line.

### BACKGROUND

Parameterizing a production line may take place, for example, when starting up a new electronics production line or when introducing a new series which is to be produced for the first time on an existing installation. This is the case in particular in production processes for industrial electronics, power electronics and microelectronics. Electronics products are produced worldwide and are subject here to different environment and boundary conditions. If a product/an assembly is now to be produced in two production lines which are physically separated from one another, this regularly constitutes a challenge. Starting up further production lines at the same location for existing products is also not trivial.

### SUMMARY

The teachings of the present disclosure may be used for simplifying location-independent scaling of production volumes to a plurality of production lines. For example, some embodiments of the teachings include a method for parameterizing an electronics production line (201) on the basis of device parameters (P20, . . . , P40) of a reference production line (200), wherein the electronics production lines (200, 201) each have at least: a device (20) for applying joining material to one or more component carriers (PCB), a placement device (30) for placing electronic components onto the component carriers (PCB), a joining device (40) for joining the electronic components to the component carriers (PCB), and a transport system (250) which is designed to transport the component carriers (PCB) through the devices (20, 30, 40), the method comprising:
parameterizing the devices (20, . . . , 40) of the electronics production line (201) on the basis of the device parameters (P20, . . . , P40) of the reference production line (201),
ascertaining actual process parameter values (ACT) in a limited region (h) around the transport system (250) of the parameterized electronics production line (201), and
ascertaining deviations (DEV) between the actual process parameter values (ACT) and reference process parameter values (REF), wherein the reference process parameter values (REF) have been acquired in a limited region (h) around the transport system (250) of the reference production line (200).

In some embodiments, the method includes ascertaining offset values (OFF) for the devices (20, . . . , 40) on the basis of the deviations (DEV).

In some embodiments, the actual process parameter values (ACT) and/or the reference process parameter values (REF) are acquired and/or have been acquired using a process parameter acquisition system (AIO) which is designed to run through the electronics production lines (200, 201) on the transport system (250).

In some embodiments, the region (h) extends from a maximum of 40 mm above a transport plane (h0) of the transport system (250) to a maximum of 30 mm below the transport plane (h0).

In some embodiments, the production lines (200, 201) each produce electronic assemblies (100) of a series (S100) and wherein at least one assembly (100) of the series (S100) has been produced on the reference production line (200).

In some embodiments, the reference process parameter values (REF) are acquired after the at least one assembly (100) has been produced on the reference production line (200).

In some embodiments, the reference process parameter values (REF) comprise at least one residual oxygen concentration and/or a temperature, in each case in the region (h) around the transport system (250) of the reference production line (200).

In some embodiments, the reference process parameter values (REF) comprise at least one acceleration profile and/or a force profile which acts on the component carriers (PCB) or assemblies (100) when they are running through the reference production line (200).

In some embodiments, when ascertaining deviations (DEV), deviations between ambient conditions, in particular temperature, air humidity and air pressure of the production lines (200, 201) are also ascertained.

In some embodiments, the same process parameter acquisition system (AIO) is used when ascertaining the actual process parameter values (ACT) and the reference process parameter values (REF).

In some embodiments, two process parameter acquisition systems (AIO) calibrated under the same ambient conditions are used when ascertaining the actual process parameter values (ACT) and the reference process parameter values (REF).

In some embodiments, a calibration data set for the process parameter acquisition system (AIO) is ascertained when ascertaining the reference process parameter values (REF).

### Transfer To Other Locations

As another example, some embodiments include a method for manufacturing a series of electronic assemblies (100) on a production line (201) which has been parameterized by one or more of the methods described herein.

As another example, some embodiments include an electronics production line (200, 201) for carrying out a method described herein, the line having: a device (20) for applying joining material to component carriers (PCB), a placement device (30) for placing electronic components onto the component carriers (PCB), a joining device (40) for joining the electronic components to the component carriers (PCB), a transport system (250) which is designed to transport the component carriers (PCB) through the devices (20, 30, 40), and at least one interface unit (210) which is designed to receive reference process parameter values (REF).

In some embodiments, the interface unit (210) is designed to ascertain deviations (DEV) and/or offset values (OFF).

### BRIEF DESCRIPTION OF THE DRAWINGS

The teachings of the present disclosure are described and explained in more detail below on the basis of the exemplary embodiments illustrated in the figures. In the figures:

FIG. 1 schematically shows a reference production line or an electronics production line;

FIG. 2 shows an electronics production line with device parameters;

FIG. 3 shows processing of the actual and reference process parameters;

FIG. 4 shows a schematic cross section through a transport system;

FIG. 5 schematically shows a process parameter acquisition system on a transport system; and

FIG. 6 schematically shows a joining device having a region.

### DETAILED DESCRIPTION

Some embodiments of the teachings herein include electronics production lines including: a device for applying joining material to one or more component carriers, a placement device for placing electronic components onto the component carriers, a joining device for joining the electronic components to the component carriers, and a transport system which is designed to transport the component carriers through the devices.

In this case, the parameterizing of the devices of the electronics production line is carried out on the basis of device parameters of the reference production line. If production lines with devices of identical construction are involved, the parameters can be adopted directly. By way of example, configuration data can thus be copied and adopted directly for the electronics production line to be parameterized and the devices thereof. If similar devices or devices from different manufacturers are involved, the process parameters to be complied with can be configured into the equivalent data fields of the devices to be parameterized. These may be, e.g., temperature specifications, feed rates, placement forces, solder temperatures (joining temperatures), etc.

Furthermore, actual process parameter values are ascertained in a limited region around the transport system of the parameterized electronics production line. As a result, it is established how the process parameters which have been configured in the devices actually have an impact in the new electronics production line and above all on the assemblies to be produced.

In this case, the region is a limited region around the transport system, in other words a region which is regularly run through by the assemblies or by the components arranged thereon and in which the conditions which are relevant to the actual process prevail. In this case, acquiring process parameters in the region allows direct conclusions to be drawn about the conditions which actually act on the assemblies and components. The parameters occurring in the region and the values thereof include, inter alia, temperatures, residual oxygen concentrations, accelerations, clocking of the line, forces occurring on the component carriers and components, and further parameters.

In some embodiments, deviations between the actual process parameter values and reference process parameter values are ascertained, wherein the reference process parameter values have been acquired in a limited region around the transport system of the reference production line. In this case, the reference production line and its reference process parameter values represent the measure of the values to be complied with, and the deviations can be tolerated if they do not exceed a definable threshold value.

In some embodiments, the method comprises ascertaining offset values for the devices of the electronics production line on the basis of the deviations. In particular, the offset values are ascertained if the deviations exceed a respective threshold value. The threshold values can be defined for each individual parameter. Depending on the device, the offset values can in this case be realized as a true offset (that is to say from a defined parameter) or as a change in the parameter value. In this case, the offset values can be stored in production documentation. In this case, the offset values are set such that the actual process parameter values of the electronics production line correspond to the reference process parameter values of the reference production line. If the deviations are too large, that is to say they exceed a second considerably much greater threshold value, it can be assumed therefrom that there is a need for maintenance or that a fault has occurred when the line is started up.

In some embodiments, the actual process parameter values and/or the reference process parameter values are acquired using a process parameter acquisition system which is designed to run through the electronics production lines on the transport system. In this case, the reference process parameter values in the reference production line are acquired or made available before the actual process parameter values are acquired. Moreover, there is no temporal dependence, and so at any time after the reference process parameter values have been determined, these can in turn be used as a reference in an installation to be newly parameterized.

In some embodiments, the region extends from a maximum of 40 mm above a transport plane of the transport system to a maximum of 30 mm below the transport plane. In particular, values of 35 mm above the transport plane and 25 mm below the transport plane have proven advantageous. In this case, the transport plane is the plane defined in that the component carriers rest on the transport system and thus the bearing surface defines a zero point or the transport plane.

In some embodiments, the production lines each produce electronic assemblies of a series of electronic assemblies, wherein at least one assembly of the series has already been produced on the reference production line. In this case, a series is defined as a number of identical electronic assemblies. Identical may be in this case, e.g., identical with regard to the “bill of materials” or slight deviations of individual components with the same layout.

The methods described herein can also be used for similar assemblies, in particular in the case of different layouts with similar components (that is to say the same power class); however, it may still be necessary here, after setting offset values, to carry out corresponding quality inspections and to adapt the offset values again.

In some embodiments, the reference process parameter values are acquired after the at least one assembly has been produced on the reference production line. In this case, quality demands on the assemblies can be checked and, if the requirements have been met, the reference process parameter values can be released and used for further electronics production lines.

In some embodiments, the reference process parameter values comprise at least one residual oxygen concentration and/or a temperature in the region around the transport system of the reference production line. Acquiring the reference process parameter values, in particular the residual oxygen concentration and/or the temperature in the region, has the great advantage that process conditions acting directly on the assemblies can thus be acquired and can accordingly also be transferred to the system to be parameterized.

In some embodiments, the reference process parameter values comprise at least one acceleration profile and/or a force profile which acts on the component carriers or assemblies which run through a reference production line. Such force or acceleration profiles can be acquired, for example, by a process parameter acquisition system which is designed to run through the reference production line. The force profile is understood to mean, for example, placement forces or further forces on the components and/or the component carriers during joining. The acceleration profile means, in particular, the accelerations which act on the component carriers or the then completed assemblies through the transport system or individual process steps.

In some embodiments, when ascertaining the deviations, deviations between ambient conditions, in particular temperature, air humidity and air pressure in the surroundings of the production lines are also taken into account. In some embodiments, after it has run through the production line, a process parameter acquisition system can still be stored for a while in the surroundings of the reference production line in order to ascertain the ambient parameters. It is likewise conceivable for ambient parameters to be acquired using separate measuring means. In this case, the surroundings are defined in such a way that the ambient conditions acting directly on the production lines prevail in the surroundings. As a rule, the surroundings stretch only a few meters around the production lines.

In some embodiments, the same process parameter acquisition system is used when ascertaining the actual process parameter values and when ascertaining the reference process parameter values. This ensures that measurement inaccuracies which through the use of different process parameter acquisition systems can influence the parameterization can be eliminated. Thus, for example, a technician can use the process parameter acquisition systems with the reference process parameter values stored thereon to start up the production line to be parameterized and directly obtain the deviations and set offset values.

In some embodiments, two process parameter acquisition systems calibrated under the same definable ambient conditions (e.g. normal conditions) are used when ascertaining the actual process parameter values and when ascertaining the reference parameter values. Thus, the process parameter acquisition systems used do not necessarily have to be calibrated at or sent from the same location but can be calibrated in the immediate vicinity of the electronics production line to be parameterized. It is likewise conceivable for process parameter values to be weighted on the basis of the ambient conditions during the calibration.

In some embodiments, a calibration data set for the process parameter acquisition system is ascertained when ascertaining the reference process parameter values. In this case, the calibration data set comprises the ambient conditions under which the reference process parameter values were acquired, and calibration data of the sensors of the process parameter acquisition system. Thus, for example, ambient conditions can therefore be stored before ascertaining the reference process parameter values in order to be able to use the digital data later without transporting the process parameter acquisition systems to a different location.

Some embodiments include a method for manufacturing a series of electronic assemblies. In this case, the series of electronic assemblies is produced on a production line, wherein the production line has been parameterized by a method according to the invention. That is to say, corresponding process parameters are ascertained on a reference production line and transferred to the production line. Deviations are furthermore ascertained in order to ensure that the series of the electronic assembly can be produced on both production lines under sufficiently identical conditions. This simplifies the transfer of production lines to other locations, wherein quality demands on the individual products, that is to say defined electronic assemblies, can remain. Scaling of electronics production is thus also possible in a simpler and more efficient manner.

Some embodiments include an electronics production line which is designed to carry out one or more of the methods described herein. For this purpose, the electronics production line has at least one device for applying joining material to component carriers. Furthermore, a placement device for placing electronic components onto the component carriers, a joining device for joining the electronic components to the component carriers, and a transport system which is designed for transporting the component carriers through the devices. Furthermore, the electronics production line has an interface unit which is designed to receive reference process parameter values. In this case, the interface unit can be in the form of an industrial controller with industrial communication interfaces. However, the interface unit can also be in the form of an edge box which is designed dedicated to the parameterization and monitoring of the process parameters and communicates, for example, with an industrial controller of the electronics production line or of the individual devices.

In some embodiments, the interface unit is designed to ascertain deviations and/or offset values. In this case, the deviations are ascertained from the reference process parameter values and the actual process parameter values. In this case, the offset values can be derived from the deviations.

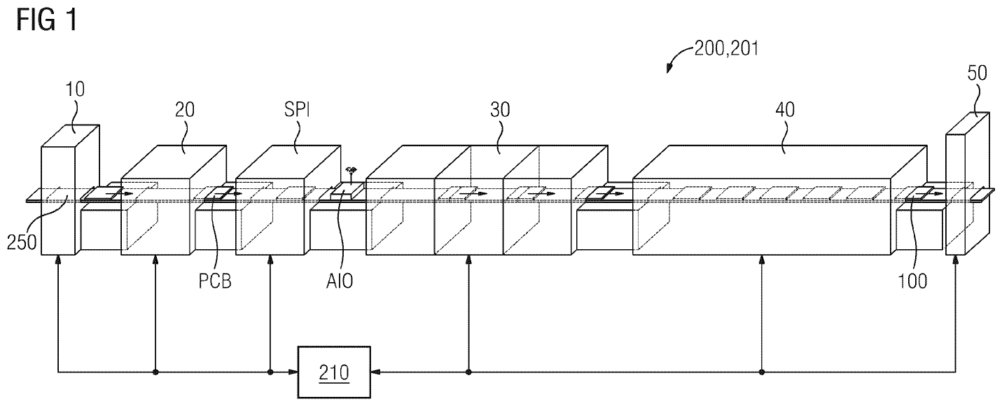

FIG. 1 schematically shows an electronics production line 200, 201, standing for a reference production line 200 and an electronics production line 201, respectively. The constituent parts of the reference production line 200 are described below, wherein these constituent parts can also be used entirely or partially in the electronics production line 201. In this case, the reference production line 200 has devices 10, . . . , 50. In this case, inter alia, a provision device 10 which is suitable for providing component carriers PCB, that is to say for example substrate materials or printed circuit boards.

Furthermore, a transport system 250 which is designed to transport the component carriers PCB through the reference production line 200 is shown. A device 20 for applying joining material can, for example, be in the form of a solder paste printer or solder paste dispenser. Sintering pastes can also be applied here. One or more placement devices 30 place components, for example SMD components, onto the component carriers PCB provided with joining materials. A joining device 40 completes the joining connections between the components and the component carriers PCB via the joining materials. This may be, for example, a reflow oven or a sintering installation.

A collecting device 50 which collects the manufactured assemblies 100 can be seen at the end of the reference production line 200. An interface unit 210 is in communication with the devices 10, . . . , 50 of the reference production line 200 and may in this case be configured to ascertain and/or output process parameters or device parameters. In this case, the electronics production line 201 is constructed in exactly the same way as the reference production line 200, wherein individual devices may originate from the same manufacturers, different manufacturers but with similar device parameters or different manufacturers. Ideally, the devices of the electronics production line 201 and those of the reference production line 200 are structurally identical. If the devices differ, then either parameters can be adopted directly as initial parameters or adapted parameters can be created on the basis of the technical data of the devices (maximum heating power, etc.).

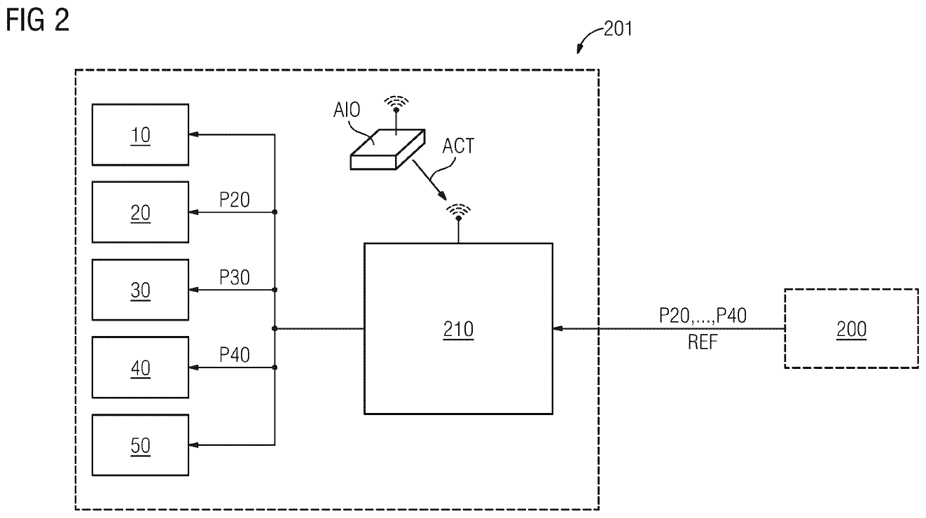

FIG. 2 schematically shows an electronics production line 201 to be parameterized, which is parameterized with device parameters P20, . . . , P40 and is checked with reference process parameter values REF of a reference production line 200 incorporating teachings of the present disclosure. In this case, the reference process parameter values REF and the process parameter values are made available to an interface unit 210 which is, for example, in the form of an industrial controller and can be used to parameterize the individual devices 10, . . . , 50. In the present case, parameters P20 are made available for the device 20 for applying joining material, parameters P30 for the placement device 30 and parameters P40 for the joining device 40.

If the devices 20, . . . , 40 are then parameterized, a process parameter acquisition system AIO can be transported on the transport system 250 through the electronics production line 201 and, in the process, acquire actual process parameter values ACT. In this case, the actual process parameter values ACT can be transferred via a wireless connection between the process parameter acquisition system AIO and, for example, the interface unit 210 and/or a start-up computer (laptop, tablet, smartphone, in each case using a program/an app).

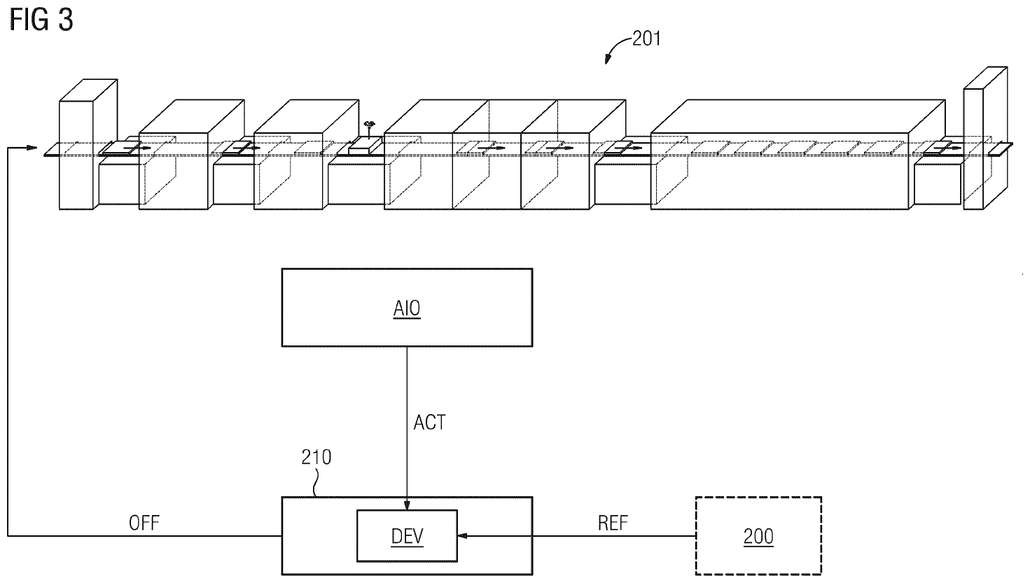

FIG. 3 schematically shows how deviations DEV are ascertained in the interface unit 210 from the actual process parameter values ACT, the electronics production line 201 parameterized with the process parameters P20, . . . , P40 and the reference process parameter values REF of the reference production line 201. Offset values for the electronics production line 201 and its devices 20, . . . , 40 can then be determined on the basis of the deviations, in order that the production conditions correspond to those of the reference production line. Should the setting of the offset values not give satisfactory results, the process can be repeated or, in the case of serious deviations, the installation can be checked (e.g. defects such as a lack of sealing such that process gas escapes).

In other words, FIG. 3 shows how, for an electronics production line 201 to be parameterized, deviations DEV are generated from the actual process parameter values ACT and the reference process parameter values REF of a reference production line 200, on the basis of which deviations the interface unit 210 creates offset values OFF for the electronics production line 201. These offset values OFF can be set directly by the interface unit 210 in the electronics production line 201; in some embodiments, it is possible for individual devices (not shown) of the electronics production line 201 to have their own control apparatuses to which the offset values OFF are communicated and which can then be set in the devices themselves via the control apparatus of the respective device. In some embodiments, individual devices have control apparatuses which manage the offset values OFF for a plurality of devices.

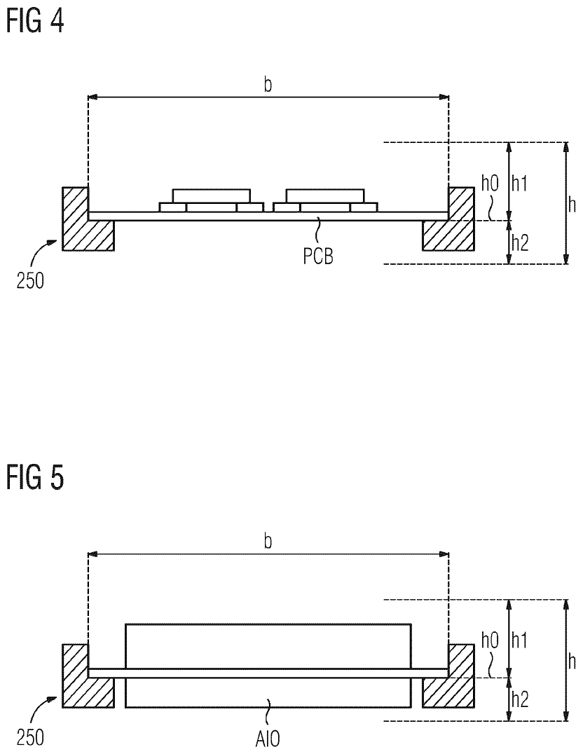

FIG. 4 shows a schematic cross section through the transport system 250, shown in FIG. 1, of the electronics production lines 200, 201 incorporating teachings of the present disclosure. The transport system 250 may, for example, be in the form of a chain-based transport system which transports the component carriers PCB, e.g. with a clamp, through the electronics production line 200, 201. In this case, the transport system 250 is capable of being adjusted in the width b so that the different component carriers PCB can be transported securely.

Furthermore, a transport plane ho which results from the support of the transport system 250 on which the component carriers PCB rest can be seen. A region h around the transport plane is likewise defined as a region h1 above the transport plane h0 and a region h2 below the transport plane h0. Values of at most 35 mm have been found to be advantageous for the region h1 above the transport system 250 and values of at most 25 mm have been found to be advantageous for the region h2 below, since these are complied with or run through in common electronics production lines 200, 201 and with common populated component carriers. It can thus be assumed therefrom that a measured value acquired in the region h represents the conditions or the process parameters as they actually act on a component carrier PCB. In this case, the width of the region h is limited to the maximum transport width b which the transport system 250 is able to provide. Best measured values arise within the region h, at the locations where, on average, most components pass. This may be, for example, centered with respect to the width b and from 1 to 5 mm above the transport plane h0. It is likewise possible for a plurality of measurement points to be distributed over the width b.

FIG. 5 schematically shows a process parameter acquisition system AIO which is transported on the transport system 250 incorporating teachings of the present disclosure. The region h and the width b are indicated analogously to FIG. 4. It can also be seen that the process parameter acquisition system AIO does not necessarily have to fill the complete region h. If the process parameter acquisition system AIO travels through the region h, a profile of the process parameter values over the route traveled can be created by acquiring process parameter values at a plurality of points or (quasi-)continuously, e.g. at a suitable sampling rate.

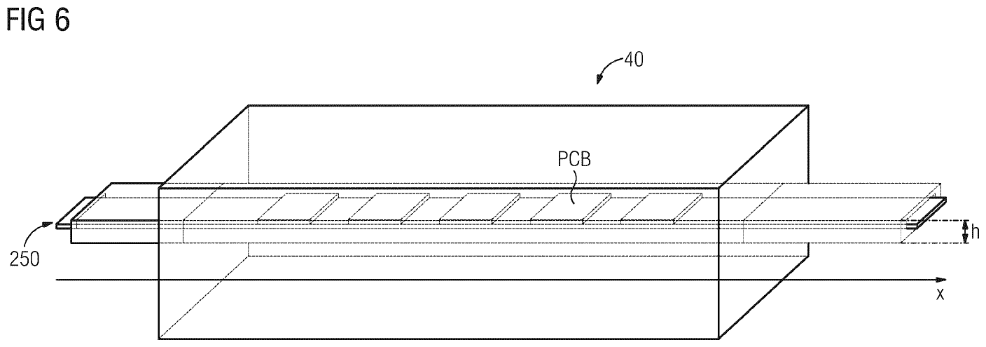

FIG. 6 schematically shows a joining device 40 incorporating teachings of the present disclosure as can be used in a reference production line 200 and a production line 201. A detail of the transport system 250 and a graphical illustration of how the region h extends through the joining device 40 along the movement direction x are shown. The region h thus forms a virtual tunnel around the transport system, in which the actual process parameter values ACT should correspond to the reference process parameter values REF. In this case, the region h is always within the respective device 10, . . . , 50 except in sections of the transport system 250 which are arranged between, upstream or downstream of the respective devices.

Some embodiments include a method for parameterizing an electronics production line (201) on the basis of device parameters (P20, . . . , P40) of a reference production line (200). The electronics production lines (200, 201) each have at least:
a device (20) for applying joining material to one or more component carriers (PCB),
a placement device (30) for placing electronic components onto the component carriers (PCB),
a joining device (40) for joining the electronic components to the component carriers (PCB), and
a transport system (250) which is designed to transport the component carriers (PCB) through the devices (20, 30, 40). In order to simplify location-independent scaling of production volumes to a plurality of production lines, the method comprises:
parameterizing the devices (20, . . . , 40) of the electronics production line (201) on the basis of the device parameters (P20, . . . , P40) of the reference production line (201),
ascertaining actual process parameter values (ACT) in a limited region (h) around the transport system (250) of the parameterized electronics production line (201),
ascertaining deviations (DEV) between the actual process parameter values (ACT) and reference process parameter values (REF), wherein the reference process parameter values (REF) have been acquired in a limited region (h) around the transport system (250) of the reference production line (200). The invention furthermore relates to a method for manufacturing a series of electronic assemblies (100) and to an electronics production line (200, 201).

### REFERENCE SIGNS

100 electronic assemblies
PCB component carrier
200 reference production line
201 electronics production line
210 interface unit
10 provision device
20 device for applying joining material
30 placement device
40 joining device
50 collecting device
P20, . . . , P40 device parameters
250 transport system
h0 transport plane
h region
h1, h2 region above/below the transport plane
SPI inspection device
REF reference process parameter values
ACT actual process parameter values
DEV deviations
OFF offset values
AIO process parameter acquisition system

What is claimed is:

1. A method for parameterizing an electronics production line using device parameters of a reference production line, wherein the electronics production lines each include:
a device to apply joining material to component carriers,
a placement device to place electronic components onto the component carriers,
a joining device to connect the electronic components to the component carriers, and
a transport system to transport the component carriers through the devices, the method comprising:
parameterizing the devices of the electronics production line using the device parameters of the reference production line;
ascertaining actual process parameter values in a limited region around the transport system of the parameterized electronics production line; and
ascertaining deviations between the actual process parameter values and reference process parameter values;
wherein the reference process parameter values have been acquired in a limited region around the transport system of the reference production line.

2. The method as claimed in claim 1, further comprising
ascertaining offset values for the devices based on the deviations.

3. The method as claimed in claim 1, wherein the actual process parameter values and/or the reference process parameter values are acquired and/or have been acquired using a process parameter acquisition system to run through the electronics production lines on the transport system.

4. The method as claimed in claim 1, wherein the limited region extends from a maximum of 40 mm above a transport plane of the transport system to a maximum of 30 mm below the transport plane.

5. The method as claimed in claim 1, wherein:
the production lines each produce electronic assemblies of a series; and
at least one assembly of the series has been produced on the reference production line.

6. The method as claimed in claim 5, wherein the reference process parameter values are acquired after the at least one assembly has been produced on the reference production line.

7. The method as claimed in claim 1, wherein the reference process parameter values comprise at least one residual oxygen concentration and/or a temperature, in each case in the region around the transport system of the reference production line.

8. The method as claimed in claim 1, wherein the reference process parameter values comprise at least one acceleration profile and/or a force profile which acts on the component carriers or assemblies when they are running through the reference production line.

9. The method as claimed in claim 1, further comprising ascertaining deviations between ambient conditions, in particular temperature, air humidity and air pressure of the production lines when ascertaining the deviations.

10. The method as claimed in claim 1, wherein the same process parameter acquisition system is used when ascertaining the actual process parameter values and the reference process parameter values.

11. The method as claimed in claim 1, wherein two process parameter acquisition systems calibrated under the same ambient conditions are used when ascertaining the actual process parameter values and the reference process parameter values.

12. The method as claimed in claim 1, wherein a calibration data set for the process parameter acquisition system is ascertained when ascertaining the reference process parameter values.

13. (canceled)

14. An electronics production line comprising:
a device to apply joining material to component carriers;
a placement device to put electronic components onto the component carriers;
a joining device to connect the electronic components to the component carriers;
a transport system to transport the component carriers (PCB) through the devices; and
an interface unit to receive reference process parameter values;
wherein the devices of the electronics production line have been parameterized using device parameters of reference production line, then actual process parameter values are ascertained in a limited region around the transport system of the parameterized electronics production line, and deviations between the actual process parameter values and reference process parameter values are ascertained and provided to the interface unit;
wherein the reference process parameter values have been acquired in a limited region around the transport system of the reference production line.

15. The electronics production line as claimed in claim 14, wherein the interface unit receives deviations and/or offset values.
